(19) United States
(12) Patent Application Publication
(10) Pub. No.: US 2012/0020071 A1
(43) Pub. Date: Jan. 26, 2012

(54) HIGH PERFORMANCE LED GROW LIGHT

(76) Inventor: CAMMIE MCKENZIE, Palmdale, CA (US)

(21) Appl. No.: 13/189,009

(22) Filed: Jul. 22, 2011

Related U.S. Application Data
(60) Provisional application No. 61/366,861, filed on Jul. 22, 2010.

(51) Int. Cl. F21V 9/00; H05K 13/00

(52) U.S. Cl. 362/231; 29/592.1

(57) ABSTRACT

High performance LED grow lights and methods of manufacturing high performance LED grow lights are disclosed. Features of a grow light may include, inter alia, LED elements with acute angle lenses, and LED distributions that optimize light intensity over a desired grow area, at wavelengths that maximize photosynthesis, plant growth and flowering. The light may also optionally provide for visibility of plant growth and the work area.

### CROSS-REFERENCE TO RELATED APPLICATIONS

Priority is claimed to U.S. Provisional Application 61/366,861, entitled “HIGH PERFORMANCE LED GROW LIGHT”, filed on Jul. 22, 2010 and identified by attorney docket number HYDR0000200.

### BACKGROUND

Light Emitting Diode (LED) technology has made significant gains in recent years. The efficiency and light output of LED's has increased exponentially since the 1960's, with a doubling occurring about every 36 months. As a result, LED technology can now be successfully deployed for grow light applications, to provide high-efficiency, low cost, safe and long-lasting grow light solutions. However, the performance of LED grow lights varies, and there is an ongoing need in the grow light industry for high-performance grow lights that maximize photosynthesis, plant growth and flowering.

### SUMMARY

High performance LED grow lights and methods of manufacturing high performance LED grow lights are disclosed. Features of a grow light may include, inter alia, LED elements with acute angle lenses, and LED distributions that optimize light intensity over a desired grow area, at wavelengths that maximize photosynthesis, plant growth and flowering. The light may also optionally provide for visibility of plant growth and the work area. Further aspects and embodiments are described below.

### BRIEF DESCRIPTION OF THE DRAWINGS

FIG. 1 illustrates side and bottom views of an example high-performance LED grow light.

FIG. 2A illustrates two example light engines comprising groups of LED elements positioned on a matrix mappable to a grow light surface.

FIG. 2B illustrates six example light engines comprising groups of LED elements positioned on a matrix mappable to a grow light surface.

FIG. 3 illustrates an LED element and an example grow area produced by an acute angle lens.

FIG. 4 illustrates side and top views of an example high-performance LED grow light arranged as a vertical tower.

### DETAILED DESCRIPTION

The illustrative embodiments provided herein are not meant to be limiting. Other embodiments may be utilized, and changes may be made, without departing from the spirit or scope of the subject matter presented here. It will be understood that aspects of the present disclosure may be arranged, substituted, combined, and designed in a wide variety of different configurations.

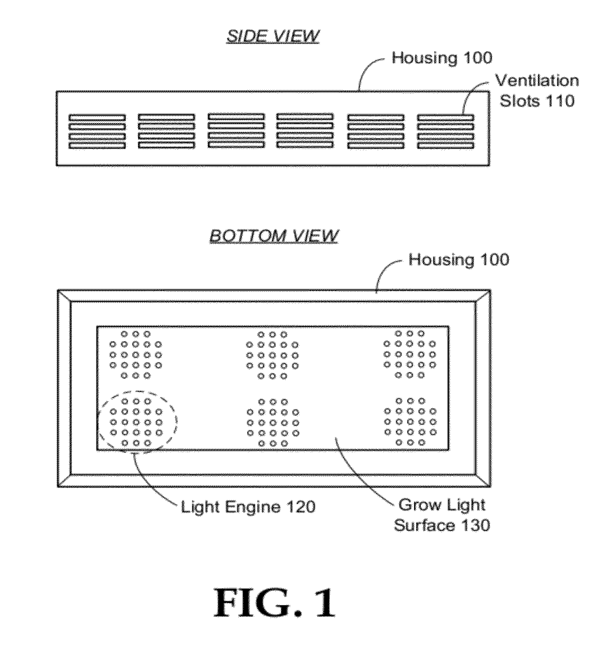

FIG. 1 illustrates side and bottom views of an example high-performance LED grow light. The side view shows a housing 100 with ventilation slots 110 allowing for cooling the grow light during operation. The bottom view shows the housing 100 and a plurality of LED elements arranged in a plurality of groups, referred to as “light engines” 120. The light engines 120 are positioned on a grow light surface 130.

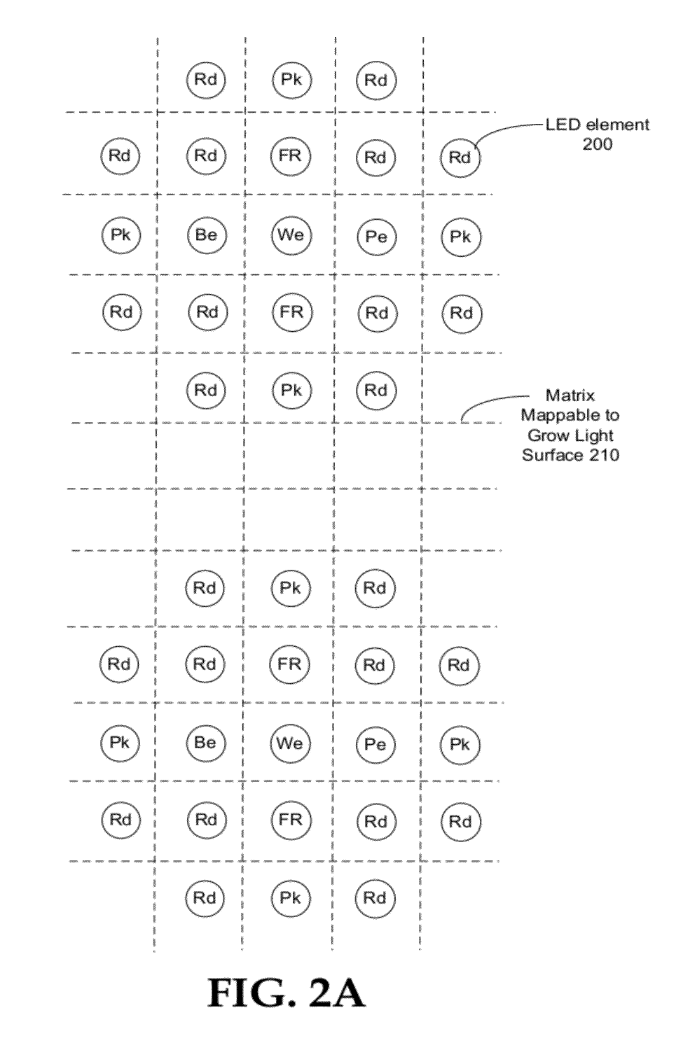

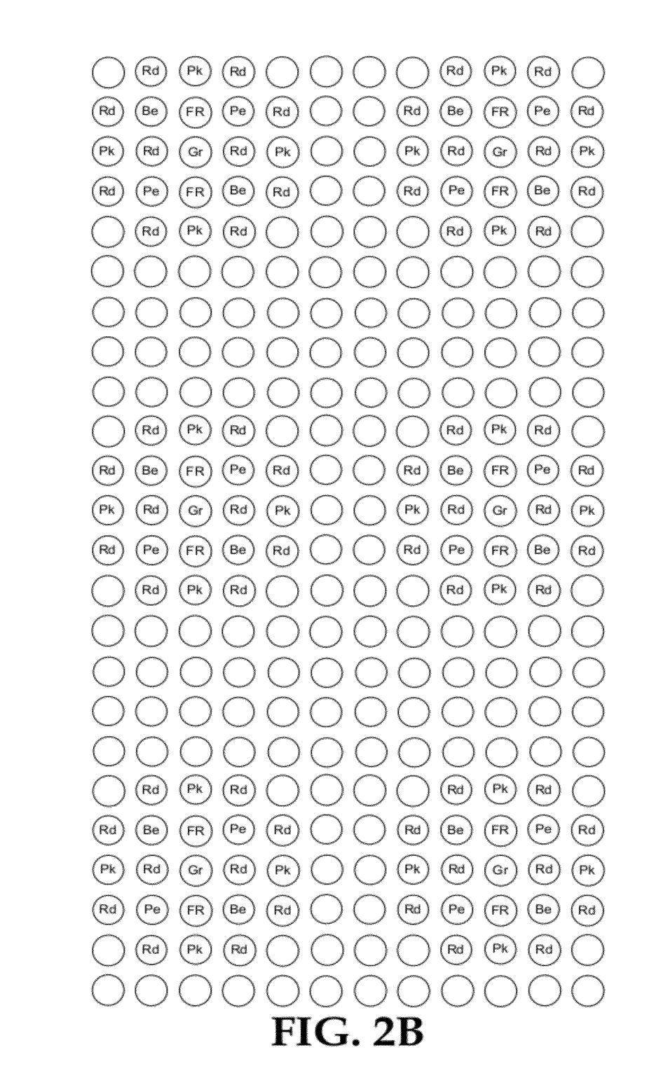

FIG. 2A illustrates two example light engines comprising groups of LED elements 200 positioned on a matrix mappable to a grow light surface 210. The example light engines comprise identical total numbers of LED elements, and identical numbers of LED elements of each of a plurality of different wavelengths. Each LED element 200 may comprise, for example, a one Watt, one-chip LED, a two Watt, two-chip LED, or a three Watt, three-chip LED.

In FIG. 2A, the total number of LED elements 200 in a light engine is 21, with 12 LED elements of Rd wavelengths, 4 LED elements of Pk wavelengths, 2 LED elements of FR wavelengths, 1 LED element of Be wavelengths, 1 LED element of Pe wavelengths, and 1 LED element of We wavelengths. The identified wavelengths may be characterized as substantially within the following ranges:

Rd (Red): wavelengths in the 650-670 nm range

Pk (Pink): wavelengths in the 630-650 nm range

FR (Far Red): wavelengths in the 730-750 nm range

Be (Blue): wavelengths in the 430-450 nm range

Pe (Purple): wavelengths in the 460-480 nm range

We (White): multi-wavelength LED producing white light (i.e. light with a color temperature of approximately 6500K)

Gr (Green): wavelengths in the 500-550 nm range

Note the light engines of FIG. 2A do not include Gr LED elements. Gr LED elements may serve similar purposes as We LED elements discussed herein, in addition to supporting photosynthesis. Gr LEDs may be used in place of We LEDs in some configurations.

The illustrated light engines may be modified in some embodiments, for example by removing LED elements of certain wavelengths, and optionally placing the removed LED elements elsewhere on the grow light surface. In order to achieve a light engine that promotes photosynthesis for many varieties of plants, in some embodiments the plurality of different wavelengths represented in a light engine may comprise any two or more of a wavelength in the 430-450 nm range, a wavelength in the 460-480 nm range, a wavelength in the 500-550 nm range, a wavelength in the 630-650 nm range, a wavelength in the 650-670 nm range, a wavelength in the 730-750 nm range, and a multi-wavelength white light wavelength distribution.

For example, in some configurations, a light engine may comprise LED elements of each of a plurality of different wavelengths, including one LED with a wavelength of approximately 440 nm (a Be wavelength), one LED with a wavelength of approximately 470 nm (a Pe wavelength), five LED's with a wavelength of approximately 640 nm (a Pk wavelength), twelve LED's with a wavelength of approximately 660 nm (an Rd wavelength), and two LED's with a wavelength of approximately 740 nm (a FR wavelength). LEDs with We wavelengths may be optionally placed elsewhere on the grow light surface, outside of the light engine groups.

In another configuration, a light engine may comprise LED elements of each of a plurality of different wavelengths, including 9 Rd LEDs, 4 Pk LEDs, 4 We LEDs, 2 FR LEDs, and 2 Be LEDs.

In some embodiments it may be advantageous to produce light engines with differing numbers of LED elements, while keeping a same ratio of represented wavelengths. Thus for example a light engine larger than those illustrated in FIG. 2A may be produced while maintaining approximately 4.8% wavelengths in the Be range, 4.8% wavelengths in the Pe range, 19% wavelengths in the Pk range, 57.1% wavelengths in the Rd range, 9.5% wavelengths in the FR range, and 4.8% multi-wavelength white light LEDs.

Light engines may comprise any total number of LED elements, arranged in any shape or pattern. Square, triangular, and rectangular light engines may be configured in some embodiments, any of which may comprise any number of LED elements depending on the desired wavelengths to be included in the light engine. Many plants deliver maximum yield and flowering times with 75% red light between 600-700 nm, 15% blue light in the 400-500 nm range, and 10% green light between 500-600 nm. Therefore, light engines generally containing a mixture of LEDs that achieve these percentages may be advantageous in some configurations. The light engines disclosed in FIG. 2A contain 75% red light between 600-700 nm, and 15% blue light from 400-500 nm, accounting for the white LED's which have a primary output between 400-500 nm, and also extend into the green 500-600 nm region.

Light engines including FR LED elements in conjunction with Rd (660 nm red) may produce photosynthesis rates above light engines that include either of these wavelengths alone. Also, Gr LEDs may result in faster flowering times and increased quantum yields for certain agricultural crops, such as tomatoes.

In general, photosynthesis relies on four primary wavelengths in order for Chlorophyll A and B to function at their optimum levels. These wavelengths are found at 439 nm, 469 nm, 642 nm, and 667 nm for most terrestrial plants. In some embodiments, LED's included in a light engine may be selected to match one or more of these wavelengths as closely as possible. While a 450 or 460 nm LED may be cheaper and more common than a 440 or 470 nm LED, and a 620 or 630 nm LED may be cheaper and more common than a 640 nm LED, the use of the most effective wavelengths for photosynthesis results in a higher performance grow light. LEDs with the most effective wavelengths for photosynthesis may be selected for light engines in a high performance grow light based on photosynthesis properties of a class of plants, or based on photosynthesis properties of specific plant species in some embodiments.

LED output bands may also be considered in selecting LED elements for use in a light engine. Many LED elements produce an output band that is about 30 nm wide, with a peak at the design wavelength that falls to zero at the edges of the band. While in general, the peak output wavelength(s) of LED elements in a light engine should coincide with the optimal wavelengths for photosynthesis, the off-peak wavelengths may also be considered, especially in the case of multi-frequency white LEDs.

LED element wavelengths within a light engine and/or in auxiliary LED elements on a grow light surface may include wavelengths designed to allow the gardener to see his/her plants and/or surrounding work area as they would normally appear in sunlight. Certain wavelengths of the white LEDs in the light engines of FIG. 2A accomplish this. In general, green reflected light allows visual monitoring of a plant's health, and checking for pests or deficiencies.

In FIG. 2A, the example light engines comprise identical distributions of LED elements having each of the different wavelengths. The LED elements are distributed in an octagonal pattern comprising an Rd, a Pk, and an Rd in the first row, an Rd, and Rd, a FR, an Rd and an Rd in the second row, a Pk, a Be, a We, a Pe, and a Pk in the third row, an Rd, and Rd, a FR, an Rd and an Rd in the fourth row, and an Rd, a Pk, and an Rd in the fifth row.

A light engine may also be configured with another distribution of LED elements. For example, the light engine described above, including 9 Rd LEDs, 4 Pk LEDs, 4 We LEDs, 2 FR LEDs, and 2 Be LEDs, may comprise an Rd, a Pk, and an Rd in the first row, an Rd, a We, a FR, a We, and an Rd in the second row, a Pk, a Be, an Rd, a Be, and a Pk in the third row, an Rd, a We, a FR, a We, and an Rd in the fourth row, and an Rd, a Pk, and an Rd in the fifth row.

The light engine described above, including 1 Be LED, 1 Pe LED, 5 Pk LED's, 12 Rd LED's, and 2 FR LED's may comprise an Rd, a Pk, and an Rd in the first row, an Rd, an Rd, a FR, an Rd and an Rd in the second row, a Pk, a Be, a Pk, a Pe, and a Pk in the third row, an Rd, an Rd, a FR, an Rd and an Rd in the fourth row, and an Rd, a Pk, and an Rd in the fifth row. It will be appreciated that numerous other distributions of LEDs are possible.

In some embodiments, light engines may be positioned by separating them by at least one row or at least one column of the matrix 201. For example, the light engines of FIG. 2A are separated by two rows. Spreading the light engines in this manner improves efficiency of the grow light by allowing the light engines to deliver an appropriate amount of light to a grow area, without wasting energy by delivering light beyond a photosynthetic saturation point of a plant.

FIG. 2B illustrates an example high-performance grow light configured with six example light engines, each light engine comprising groups of LED elements positioned on a matrix mappable to a grow light surface. The six light engines are identical, and are separated by two rows of a matrix in one direction (parallel to a first axis of the matrix), and four rows of the matrix in the other direction (parallel to a second axis of the matrix). In FIG. 2B, each light engine comprises 2 Be LED's, 2 Pe LED's, 4 Pk LED's, 10 Rd LED's, 2 FR LED's, and 1 Gr LED. Each light engine may comprise an Rd, a Pk, and an Rd in the first row, an Rd, a Be, a FR, a Pe and an Rd in the second row, a Pk, an Rd, a Gr, an Rd, and a Pk in the third row, an Rd, a Pe, a FR, a Be and an Rd in the fourth row, and an Rd, a Pk, and an Rd in the fifth row, to produce approximately 9.5% wavelengths in the Be range, 9.5% wavelengths in the Pe range, 19% wavelengths in the Pk range, 48% wavelengths in the Rd range, 9.5% wavelengths in the FR range, and 4.8% wavelengths in the Gr range.

It should be emphasized that while various specific light engine configurations are disclosed herein, those of skill in the art will appreciate, with the benefit of this disclosure, that other light engine configurations may be made in accordance with the teachings provided herein. The technology permits a wide variety of configurations and light engines of differing numbers of LED's, differing shapes, and differing patterns may be made. Some grow lights may provide a plurality of identical light engines as illustrated in FIG. 2B, while others may provide two or more different light engine configurations within a single grow light.

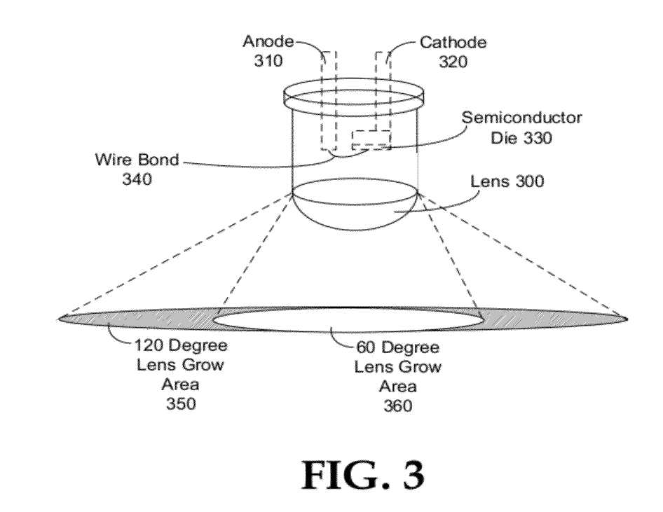

FIG. 3 illustrates an example LED element and an example grow area produced by an acute angle lens. The LED element may comprise a lens 300, an anode 310, a cathode 320, a semiconductor die 330 and a wire bond 340. The LED produces light by applying a potential difference across the semiconductor die 330 via the anode 310 and wire bond 340 and cathode 320. The potential difference causes the semiconductor die 330 to release light of a selected wavelength or wavelengths.

A 120° lens will cause an LED element to illuminate a grow area 350 at a first intensity level, while an acute angle lens, defined herein as a lens having an angle less than 120°, will cause an LED element to illuminate a grow area smaller than that illuminated by the 120° lens, with an intensity greater than the 120° lens. For example, a 60° lens will illuminate a grow area 360 with greater intensity than the 120° lens.

In some embodiments, a high performance LED grow light may comprise a plurality of LED elements on a grow light surface, wherein at least one of the plurality of LED elements comprises an acute angle lens defining a grow area illuminated by the LED element. In some embodiments, substantially all of the LED elements may comprise acute angle lenses. In some embodiments, acute angle lenses in substantially all of the LED elements may comprise 60° lenses. In some embodiments, acute angle lenses in substantially all of the LED elements may comprise lenses with angles less than 60°. Furthermore, the plurality of LED elements may comprise LED elements of each of a plurality of different wavelengths, as described herein,

A method of manufacturing a high performance LED grow light disclosed herein may include, inter alia, defining a light engine comprising a total number of LED elements and a defined number of LED elements at each of a plurality of wavelengths, wherein the defined number of LED elements at each of a plurality of wavelengths are defined to optimize photosynthesis of a plant. A grow area for the LED grow light may be identified, and a plurality of light engines may be positioned on a grow light surface to optimize illumination of the grow area according to the photosynthesic needs of the plant. In some embodiments, the LED's of the light engine may comprise acute angle lenses, as described herein. Also, the number of LED elements at each of the plurality of wavelengths may be further defined by wavelengths that facilitate visual inspection of the plant. For example, some of the wavelengths of the multi-wavelength white light LED's disclosed herein may not meaningfully contribute to photosynthesis, but may allow for easier visual inspection of a plant under the grow light, as well as any work area underneath the grow light.

In some configurations, a grow light according to this disclosure may comprise a housing approximately 16 inches long, 8.5 inches wide, and 3.5 inches thick, with a net weight of approximately 13 pounds. Sixty three (63) one-Watt high power LED's, with 60° lenses may be grouped into 3 light engines on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Three 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 12×18 inches, when the light is positioned about 6 inches over the plant canopy, with a maximum coverage area of about 18×24 inches achievable by raising the light.

In some configurations, a grow light according to this disclosure may comprise a housing approximately 19 inches long, 12.5 inches wide, and 3.5 inches thick, with a net weight of approximately 13 pounds. One hundred twenty six (126) one-Watt high power LED's, with 60° lenses may be grouped into 6 light engines on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Six 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 18×30 inches, when the light is positioned about 12 inches over the plant canopy, with a maximum coverage area of about 24×36 inches achievable by raising the light.

In some configurations, a grow light according to this disclosure may comprise a housing approximately 19 inches long, 19 inches wide, and 3.5 inches thick, with a net weight of approximately 19 pounds. Three hundred forty five (3455) one-Watt high power LED's, with 60° lenses may be grouped into 16 light engines on the grow light surface, with nine single LEDs also positioned on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Five 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 30×30 inches, when the light is positioned about 6 inches over the plant canopy, with a maximum coverage area of about 36×36 inches achievable by raising the light.

In some configurations, a grow light according to this disclosure may comprise a housing approximately 19 inches long, 19 inches wide, and 3.5 inches thick, with a net weight of approximately 17 pounds. Two hundred five (205) one-Watt high power LED's, with 60° lenses may be grouped into 9 light engines on the grow light surface, with four groups of four LEDs also positioned on the grow light surface. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light. Five 1.5 Watt fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The optimal grow area may be about 36×36 inches, when the light is positioned about 12 inches over the plant canopy, with a maximum coverage area of about 42×42 inches achievable by raising the light.

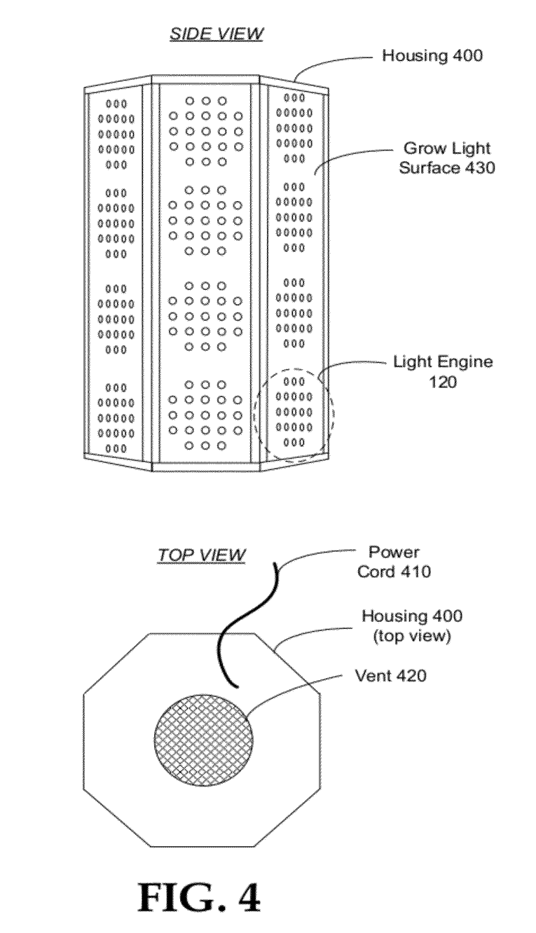

FIG. 4 illustrates side and top views of an example high-performance LED grow light arranged as a vertical tower. The tower may comprise, for example, a housing 400 that is arranged to stand vertically, to provide one or more vertically oriented grow light surfaces such as 430. Light engines such as 120, comprising a plurality of LED elements, may be arranged in a vertical orientation on one or more of the vertically oriented grow light surfaces 430. In some embodiments, the tower may comprise a plurality of side walls, each side wall comprising a grow light surface, the tower thereby emitting light outwardly around the full perimeter of the tower. For example, the tower may take a hexagonal shape as shown, thereby providing six vertical side walls. Each side wall may comprise a grow light surface and each grow light surface may comprise a plurality of light engines. A power cord 410 supplies power to the unit and a vent 420 allows one or more fans inside the unit to draw air through the unit for cooling.

In some configurations, a vertical grow light according to this disclosure may comprise, for example, a housing approximately 21 inches tall and 10.5 inches wide, with a net weight of approximately 35 pounds. Five hundred and four (504) one-Watt high power LED's, with 90° lenses may be grouped into 24 light engines on the six grow light surfaces, as illustrated in FIG. 4. Alternatively, additional luminosity may be achieved in tower configurations using a two Watt and three Watt (two chip and three chip) LED's. Each light engine may comprise one or more LED's with 440 nm wavelengths, 470 nm wavelengths, 640 nm wavelengths, and 660 nm wavelengths, and/or white and far red LEDs. The grow light may produce approximately 85% red, 10% blue, and 5% white light.

One or more fans may be positioned within the housing to cool the unit. A 6 foot long standard 110 volt outlet power cable (or 220 volt for units to be sold outside the United States) may supply power to the unit. The unit may comprise an on/off switch and hangars for hanging the unit over a grow area. The unit may also rest on the floor, with the vertical grow light surfaces extending upwards. The optimal grow area may be a volume extending from the grow light surfaces to about 36 inches therefrom and about 36 inches above and below the top and bottom of the grow light. The light may be designed for optimal positioning about 6-12 inches away from plants.

While various embodiments have been disclosed herein, other aspects and embodiments will be apparent to those skilled in art.

1. A high performance Light Emitting Diode (LED) grow light, comprising:
a plurality of LED elements arranged in a plurality of groups on a grow light surface;
wherein two or more of the groups comprise an identical total number of LED elements, and an identical number of LED elements of each of a plurality of different wavelengths.

2. The high performance Light Emitting Diode (LED) grow light of claim 1, wherein two or more of the groups comprise an identical number and distribution of LED elements having each of the different wavelengths.

3. The high performance Light Emitting Diode (LED) grow light of claim 1, wherein the plurality of different wavelengths comprise two or more of: a wavelength in the 430-450 nm range, a wavelength in the 460-480 nm range, a wavelength in the 500-550 nm range, a wavelength in the 630-650 nm range, a wavelength in the 650-670 nm range, a wavelength in the 730-750 nm range, and a multi-wavelength white light wavelength distribution.

4. The high performance Light Emitting Diode (LED) grow light of claim 1, wherein the plurality of different wavelengths comprise approximately 4.8% wavelengths in the 430-450 nm range, 4.8% wavelengths in the 460-480 nm range, 19% wavelengths in the 630-650 nm range, 57.1% wavelengths in the 650-670 nm range, 9.5% wavelengths in the 730-750 nm range, and 4.8% multi-wavelength white light distribution.

5. The high performance Light Emitting Diode (LED) grow light of claim 1, wherein the LED elements of each of a plurality of different wavelengths comprise one LED with a wavelength of approximately 440 nm, one LED with a wavelength of approximately 470 nm, four LED's with a wavelength of approximately 640 nm, twelve LED's with a wavelength of approximately 660 nm, two LED's with a wavelength of approximately 740 nm, and one multi-wavelength LED with a color temperature of approximately 6500K.

6. The high performance Light Emitting Diode (LED) grow light of claim 1, wherein the LED elements of each of a plurality of different wavelengths comprise one LED with a wavelength of approximately 440 nm, one LED with a wavelength of approximately 470 nm, five LED's with a wavelength of approximately 640 nm, twelve LED's with a wavelength of approximately 660 nm, and two LED's with a wavelength of approximately 740 nm.

7. The high performance Light Emitting Diode (LED) grow light of claim 1, wherein two or more of the groups are separated by at least one row or at least one column of a matrix mappable to the grow light surface.

8. The high performance Light Emitting Diode (LED) grow light of claim 1, wherein two or more of the groups comprise an octagonal pattern comprising 21 LEDs.

9. The high performance Light Emitting Diode (LED) grow light of claim 1, wherein at least one of the plurality of LED elements comprises an acute angle lens defining a grow area illuminated by the LED element.

10. The high performance Light Emitting Diode (LED) grow light of claim 9, wherein the acute angle lens is a less than 120 degree lens.

11. The high performance Light Emitting Diode (LED) grow light of claim 1, wherein the grow light surface is a vertically oriented surface.

12. The high performance Light Emitting Diode (LED) grow light of claim 11, wherein the grow light is in a tower configuration.

13. The high performance Light Emitting Diode (LED) grow light of claim 12, wherein the tower comprises a plurality of side walls, each side wall comprising a grow light surface, the tower thereby emitting light outwardly around the full perimeter of the tower.

14. A high performance Light Emitting Diode (LED) grow light, comprising:
a plurality of LED elements on a grow light surface;
the plurality of LED elements comprising LED elements of each of a plurality of different wavelengths; and
at least one of the LED elements comprising an acute angle lens defining a grow area illuminated by the LED element.

15. The high performance Light Emitting Diode (LED) grow light of claim 14, wherein the acute angle lens is a less than 120 degree lens.

16. The high performance Light Emitting Diode (LED) grow light of claim 14, wherein the acute angle lens is a 60 degree lens.

17. The high performance Light Emitting Diode (LED) grow light of claim 14, wherein the acute angle lens is a less than 60 degree lens.

18. The high performance Light Emitting Diode (LED) grow light of claim 14, wherein substantially all of the plurality of LED elements comprise an acute angle lens defining a grow area illuminated by the LED element.

19. A method of manufacturing a high performance LED grow light, comprising:
defining a light engine comprising a total number of LED elements and a defined number of LED elements at each of a plurality of wavelengths, wherein the defined number of LED elements at each of a plurality of wavelengths are defined to optimize photosynthesis of a plant;
defining a grow area for the LED grow light; and
positioning a plurality of light engines on a grow light surface to optimize illumination of the grow area according to the photosynthesic needs of the plant.

20. The method of claim 19, wherein the LED's of the light engine comprise acute angle lenses.

21. The method of claim 19, wherein the number of LED elements at each of a plurality of wavelengths are further defined by wavelengths that facilitate visual inspection of the plant.
